(19) United States
(12) Patent Application Publication
(10) Pub. No.: US 2025/0298322 A1
(43) Pub. Date: Sep. 25, 2025

(54) DIRECT IMAGING SYSTEM AND DIRECT IMAGING METHOD

(71) Applicant: SCREEN Holdings Co., Ltd., Kyoto (JP)

(72) Inventors: Yoshinao NORIMITSU, Kyoto (JP); Kazuhiro NAKAI, Kyoto (JP)

(73) Assignee: SCREEN Holdings Co., Ltd., Kyoto (JP)

(21) Appl. No.: 19/071,709

(22) Filed: Mar. 5, 2025

(30) Foreign Application Priority Data
Mar. 25, 2024 (JP) 2024-048053

(51) Int. Cl. G03F 7/00; G03F 7/20

(52) U.S. Cl. CPC G03F 7/704; G03F 7/2057

(57) ABSTRACT

A direct imaging system includes an optical modulator having multiple elements arranged corresponding to a sub scanning direction and for modulating light from a light source, and an exposure head for exposing the substrate with the light modulated by the optical modulator. A control part relatively moves the exposure head in a main scanning direction to expose the sub exposure area with the light modulated using a selection element, and after the sub exposure area is exposed, relatively moves the exposure head an amount corresponding to a sub exposure width in the sub scanning direction. Accordingly, exposure can be continued even if there is a defect in the optical modulator.

### CROSS-REFERENCE TO RELATED APPLICATIONS

This application claims the priority benefit of Japan Application No. 2024-048053, filed on Mar. 25, 2024. The entirety of the above-mentioned patent application is hereby incorporated by reference herein and made a part of this specification.

### BACKGROUND OF THE INVENTION

### Field of the Invention

A technology disclosed in the present specification relates to exposure of a substrate. Examples of the substrate to be treated include a semiconductor wafer, a glass substrate for liquid crystal display devices, a substrate for flat panel displays (FPDs) such as organic EL (electroluminescence) display devices, a substrate for optical disks, a substrate for magnetic disks, a substrate for magneto-optical disks, a glass substrate for photomasks, a ceramic substrate, a substrate for field emission displays (FEDs), and a substrate for solar cells.

### Description of the Background Art

In a direct imaging system (maskless exposure device) that performs direct exposure without using a photomask, a method is widely used in which an optical modulator such as a digital micromirror device (DMD) or grating light valve (GLV; registered trademark) is used instead of a photomask, and exposure is performed by scanning a stage while operating the optical modulator in accordance with exposure data.

Here, the optical modulator is a micro electro mechanical system (MEMS) having a fine and complex structure, and there are concerns about failure or performance defects.

With respect to this, for example, Japanese Patent Laid-Open No. 2023-122118 discloses a technology in which an exposure area of an exposure head where a failure is detected is compensated by another exposure head.

The technology shown in Japanese Patent Laid-Open No. 2023-122118 is not applicable in cases where a defect occurs in an optical modulator in an exposure device including only a single exposure head.

### SUMMARY OF THE INVENTION

The present disclosure is directed to a direct imaging system and a direct imaging method.

One aspect of the present disclosure provides a direct imaging system, including: a light source; an optical modulator, having a plurality of elements arranged corresponding to a sub scanning direction, the optical modulator being for modulating light from the light source; an exposure head, for exposing a substrate with the light modulated by the optical modulator; a first driver, for relatively moving the exposure head with respect to the substrate in a main scanning direction intersecting the sub scanning direction; a second driver, for relatively moving the exposure head with respect to the substrate in the sub scanning direction; and a control part, for controlling a modulation state of the light in the optical modulator, an operation of the first driver, and an operation of the second driver. At least one of the elements being some of a plurality of the elements of the optical modulator is a selection element. An area exposed via the exposure head with the light modulated using the selection element is a sub exposure area. A width of the sub exposure area in the sub scanning direction is a sub exposure width. The control part relatively moves the exposure head in the main scanning direction to expose the sub exposure area with the light modulated using the selection element, and, after the sub exposure area is exposed, relatively moves the exposure head an amount corresponding to the sub exposure width in the sub scanning direction.

Even if there is a defect in the optical modulator, light modulation and further exposure can be performed using a selection element having no defects.

One aspect of the present disclosure provides a direct imaging method for a substrate using a direct imaging system, in which the direct imaging system includes an optical modulator having a plurality of elements arranged corresponding to a sub scanning direction, the optical modulator being for modulating light from a light source, and an exposure head for exposing the substrate with the light modulated by the optical modulator. The direct imaging method includes the following processes. At least one of the elements being some of a plurality of the elements of the optical modulator is selected as a selection element. An area exposed via the exposure head with the light modulated using the selection element is defined as a sub exposure area. A width of the sub exposure area in the sub scanning direction is defined as a sub exposure width. The exposure head is relatively moved in a main scanning direction intersecting the sub scanning direction to expose the sub exposure area with the light modulated using the selection element. After the sub exposure area is exposed, the exposure head is relatively moved an amount corresponding to the sub exposure width in the sub scanning direction.

Even if there is a defect in the optical modulator, light modulation and further exposure can be performed using a selection element having no defects.

Hence, an object of the present disclosure is to continue exposure even if there is a defect in the optical modulator.

### BRIEF DESCRIPTION OF THE DRAWINGS

FIG. 1 is a side view showing a configuration of an exposure device according to an embodiment.

FIG. 2 is a plan view showing a configuration of the exposure device according to an embodiment.

FIG. 3 illustrates a configuration of an optical modulator of an illumination optical system.

FIG. 4 illustrates an example of a relationship between an exposure area on a substrate and multiple exposure heads.

FIG. 5 conceptually illustrates a configuration of multiple exposure heads.

FIG. 6 conceptually illustrates a connection configuration between each driver of the exposure device and a control part.

FIG. 7 illustrates an example of a relationship between the exposure area on the substrate, a head corresponding area of the exposure head, and a selection ribbon of the optical modulator.

FIG. 8 illustrates an example of a relationship between the exposure area on the substrate and the head corresponding area of the exposure head.

FIG. 9 illustrates another example of the relationship between the exposure area on the substrate, the head corresponding area of the exposure head, and the selection ribbon of the optical modulator.

FIG. 10 illustrates an example of the relationship between the exposure area on the substrate and the head corresponding area of the exposure head.

FIG. 11 illustrates an example of the relationship between the exposure area on the substrate and the head corresponding area of the exposure head.

FIG. 12 illustrates another example of the relationship between the exposure area on the substrate, the head corresponding area of the exposure head, and the selection ribbon of the optical modulator.

FIG. 13 illustrates an example of the relationship between the exposure area on the substrate and the head corresponding area of the exposure head.

FIG. 14 illustrates an example of the relationship between the exposure area on the substrate and the head corresponding area of the exposure head.

FIG. 15 illustrates an example of variations in exposure amount for each sub exposure area.

### DESCRIPTION OF THE PREFERRED EMBODIMENTS

Embodiments will be hereinafter described with reference to the accompanying drawings. In the following embodiments, detailed features or the like are also shown for the purpose of describing the technology, but these are examples and not all of them are necessarily essential features for the embodiments to be implemented.

The drawings are schematically shown. For the convenience of description, configurations may be omitted or simplified in the drawings as appropriate. The sizes and correlations between positions of configurations shown in different drawings are not necessarily accurately depicted and may be modified as appropriate. In drawings that are not cross-sectional views, such as plan views, hatching may be added to facilitate understanding of the content of the embodiments.

In the following description, similar components are assigned the same reference numerals for illustration, and their names and functions are also considered to be similar. Accordingly, detailed descriptions of these components may be omitted to avoid duplication.

In the description provided in the present specification, unless specifically stated otherwise, expressions such as “including,” “comprising,” or “having” a certain component are not exclusive expressions that exclude other components.

In the description provided in the present specification, even if ordinal numbers such as “first” or “second” are used, these terms are used for convenience to facilitate understanding of the content of the embodiments, and the content of the embodiments is not limited to any order that may arise from these ordinal numbers.

In the description provided in the present specification, expressions such as “positive A-axis direction” or “negative A-axis direction” define a direction along an arrow of said A axis shown in the drawings as the positive direction, and a direction opposite to the arrow of said A axis shown in the drawings as the negative direction.

In the description provided in the present specification, even if terms meaning specific positions or directions, such as “up,” “down,” “left,” “right,” “side,” “bottom,” “front,” or “back” are used, these terms are used for convenience to facilitate understanding of the content of the embodiments and do not relate to the actual position or direction when the embodiments are implemented.

### EMBODIMENTS

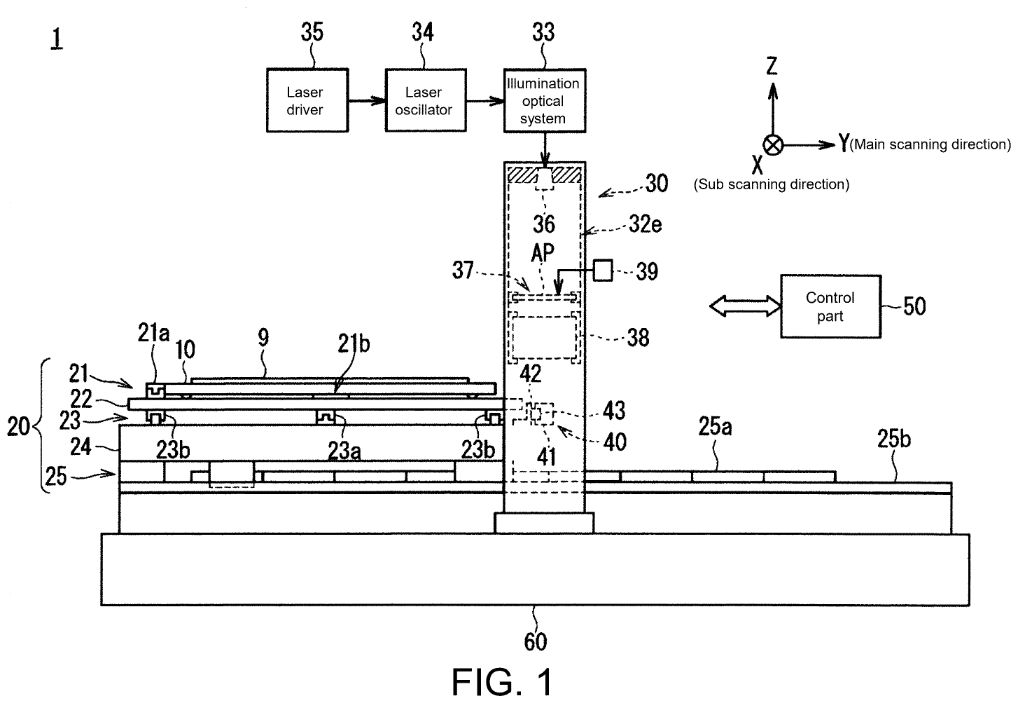

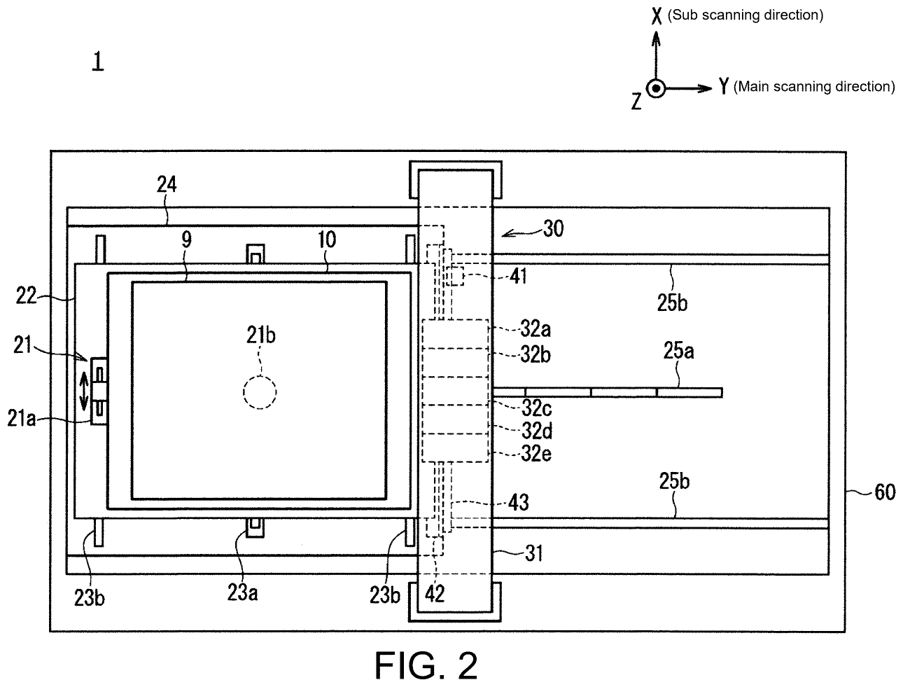

FIG. 1 is a side view showing a configuration of an exposure device (direct imaging system) according to the present embodiment. FIG. 2 is a plan view showing a configuration of the exposure device (direct imaging system) according to the present embodiment.

As shown in the examples in FIG. 1 and FIG. 2, an exposure device 1 includes: a stage 10, for holding a substrate 9; a stage driver 20, connected to the stage 10; a head part 30, having multiple exposure heads (exposure head 32a, exposure head 32b, exposure head 32c, exposure head 32d, and exposure head 32e) arranged in an X-axis direction; and a control part 50, for controlling an operation of each driver in the device. The control part 50 controls a control target by executing a program stored in an internal or external recording medium (such as volatile or non-volatile memory, such as HDD, RAM, ROM, or flash memory), and is composed of, for example, a central processing unit (CPU), a microprocessor, or a microcomputer. The exposure device 1 may include an irradiation light capturing part 40 for capturing light (irradiation light) irradiated from each exposure head.

The stage 10 is a holding part having a flat plate-like outer shape and for arranging and holding the substrate 9 in a horizontal position on its upper surface. Multiple suction holes (not shown here) are formed on the upper surface of the stage 10. Hence, when the substrate 9 is arranged on the stage 10, the substrate 9 is fixed to the upper surface of the stage 10 by a suction pressure of the suction holes. On a surface of the substrate 9 held on the stage 10, a layer of a photosensitive material such as color resist is formed.

The stage driver 20 is a mechanism for moving the stage 10 in a main scanning direction (Y-axis direction), a sub scanning direction (X-axis direction), and a rotation direction (rotation direction around the Z-axis). The stage driver 20 includes: a rotation mechanism 21, rotating the stage 10; a support plate 22, rotatably supporting the stage 10; a sub scanning mechanism 23, moving the support plate 22 in the sub scanning direction; a base plate 24, supporting the support plate 22 via the sub scanning mechanism 23; and a main scanning mechanism 25, moving the base plate 24 in the main scanning direction.

The rotation mechanism 21 includes a linear motor 21a that is composed of a mover attached to an end in the negative Y-axis direction of the stage 10 and a stator laid on an upper surface of the support plate 22. A rotary shaft 21b is provided between a central lower side of the stage 10 and the support plate 22. Hence, when the linear motor 21a is operated, the mover moves in the X-axis direction along the stator, and the stage 10 is rotated within a predetermined angular range about the rotary shaft 21b on the support plate 22.

The sub scanning mechanism 23 includes a linear motor 23a that is composed of a mover attached to a lower surface of the support plate 22 and a stator laid on an upper surface of the base plate 24. A pair of guide parts 23b extending in the sub scanning direction are provided between the support plate 22 and the base plate 24. Hence, when the linear motor 23a is operated, the support plate 22 moves in the sub scanning direction along the guide parts 23b on the base plate 24. As the support plate 22 moves in the sub scanning direction, the substrate 9 also moves in the sub scanning direction, thereby relatively moving an exposure head in the sub scanning direction with respect to the substrate 9.

The main scanning mechanism 25 includes a linear motor 25a that is composed of a mover attached to a lower surface of the base plate 24 and a stator laid on a base 60 of the exposure device 1. A pair of guide parts 25b extending in the main scanning direction are provided between the base plate 24 and the base 60. Hence, when the linear motor 25a is operated, the base plate 24 moves in the main scanning direction along the guide parts 25b on the base 60. As the base plate 24 moves in the main scanning direction, the substrate 9 also moves in the main scanning direction, thereby relatively moving an exposure head in the main scanning direction with respect to the substrate 9.

The head part 30 is a mechanism for irradiating pulse light of a predetermined pattern onto an upper surface of the substrate 9 held on the stage 10. The head part 30 includes: a frame 31, disposed on the base 60 so as to straddle the stage 10 and the stage driver 20; and five exposure heads (exposure head 32a, exposure head 32b, exposure head 32c, exposure head 32d, and exposure head 32e), attached at equal intervals along the sub scanning direction to the frame 31. Each exposure head is connected to one laser oscillator 34 via an illumination optical system 33. A laser driver 35 is connected to the laser oscillator 34.

Hence, when the laser driver 35 is operated, pulse light is emitted from the laser oscillator 34, and the emitted pulse light is introduced into each exposure head via the illumination optical system 33.

The illumination optical system 33 includes at least one optical modulator such as GLV (registered trademark) or DMD that modulates the pulse light emitted from the laser oscillator 34. A configuration of the illumination optical system 33 will be described later.

Provided inside each exposure head are: an emission part 36, for emitting the pulse light introduced from the illumination optical system 33 downward; an aperture unit 37, for partially shielding pulse light; and a projection optical system 38, for forming an image of pulse light onto the upper surface of the substrate 9. An aperture AP being a glass plate with a predetermined light shielding pattern formed thereon is set in the aperture unit 37. The pulse light emitted from the emission part 36 is partially shielded when passing through the aperture AP set in the aperture unit 37, and, as a light beam of a predetermined pattern, enters the projection optical system 38. By irradiating the pulse light that has passed through the projection optical system 38 onto the upper surface of the substrate 9, a predetermined pattern is drawn (exposed) on the photosensitive material on the substrate 9.

As conceptually shown in the example in FIG. 1, each exposure head is provided with an aperture driver 39 for adjusting a position of the aperture AP set in the aperture unit 37. By adjusting a horizontal position (including inclination within a horizontal plane) of the aperture AP, the aperture driver 39 is able to select a pattern to be projected onto the substrate 9 or adjust a projection position of the pattern. By shielding an entire irradiation area of the pulse light with a light shielding part of the aperture AP, the aperture driver 39 is also able to prohibit the irradiation of pulse light. The aperture driver 39 can be configured, for example, by combining multiple linear motors.

When one exposure in the main scanning direction ends, generally, in the exposure device 1, the stage 10 is moved an amount corresponding to a full exposure width W in the sub scanning direction, and pulse light is irradiated from each exposure head while the stage 10 is moved again in the main scanning direction. In this manner, generally, in the exposure device 1, by repeatedly performing drawing (exposure) in the main scanning direction a predetermined number of times (for example, 4 times) while shifting the substrate 9 in the sub scanning direction at intervals of the full exposure width W of the exposure head, a pattern for color filters is formed on the substrate 9.

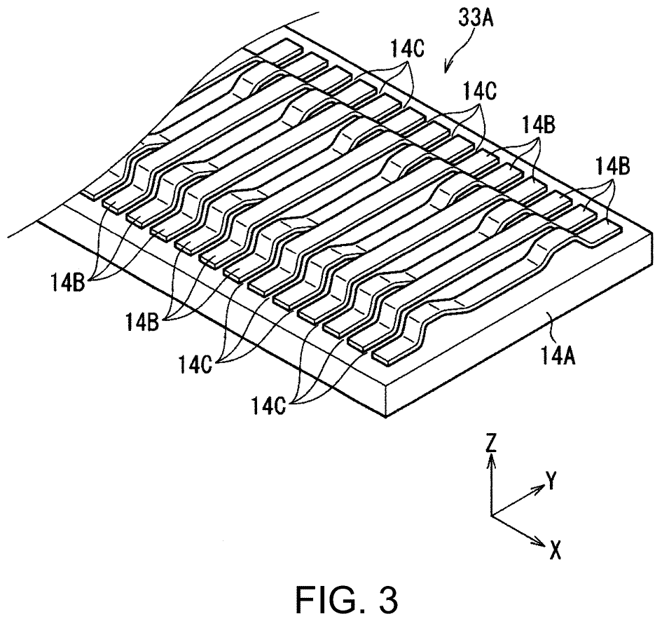

FIG. 3 illustrates an example of a configuration of an optical modulator 33A of the illumination optical system 33. As illustrated in FIG. 3, the optical modulator 33A includes: a substrate 14A; and multiple ribbons 14B (microbridges) being movable gratings, arranged in parallel on the substrate 14A. Multiple slits 14C are formed between the multiple ribbons 14B.

In each ribbon 14B, portions other than ends are located apart from the substrate 14A, a lower surface facing the substrate 14A is composed of a flexible member made of SiNx or the like, and an upper surface opposite to the lower surface is composed of a reflective electrode film made of a single-layer metal film such as aluminum.

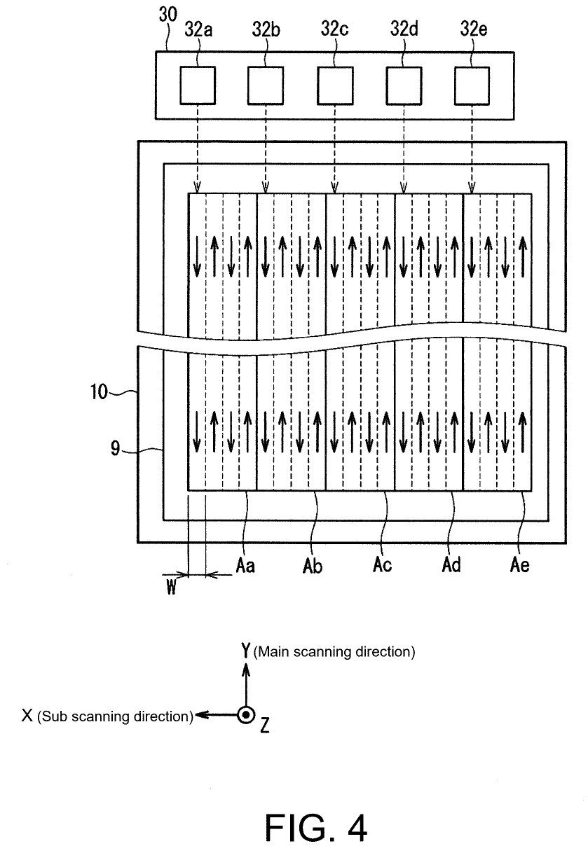

The multiple ribbons 14B are arranged corresponding to the sub scanning direction. In FIG. 3, the multiple ribbons 14B are arranged along the X-axis direction. It is sufficient that the multiple ribbons 14B are arranged corresponding to each exposure area (sub exposure area to be described later) in the sub scanning direction in FIG. 4 to be described later. In practice, the multiple ribbons 14B do not have to be arranged in the same direction as the sub scanning direction. In the case where the optical modulator 33A is a DMD, it is sufficient that some of multiple micromirrors arranged in a two-dimensional manner are arranged corresponding to each exposure area (sub exposure area to be described later) in the sub scanning direction in FIG. 4 to be described later.

The optical modulator 33A is driven and controlled by turning on/off a voltage applied between the ribbon 14B and the substrate 14A. When the voltage applied between the ribbon 14B and the substrate 14A is turned on, an electrostatic attraction force is generated between the ribbon 14B and the substrate 14A due to electrostatically induced charges, and the ribbon 14B is bent toward the substrate 14A. On the other hand, when the voltage applied between the ribbon 14B and the substrate 14A is turned off, the aforementioned bending is eliminated, and the ribbon 14B separates from the substrate 14A.

Generally, one pixel is composed of multiple, for example, 6 ribbons 14B. By alternately arranging the ribbons 14B to which voltage is applied, a diffraction grating can be generated by the application of voltage, and light modulation can be performed.

Based on exposure data stored in advance in a memory or the like, the ribbon 14B of the optical modulator 33A is controlled by the control part 50, and light modulated for each pixel is input to the emission part 36.

Each exposure head is capable of exposing multiple exposure areas. For example, the exposure head 32a is capable of exposing an exposure area Aa and an exposure area Ab; the exposure head 32b is capable of exposing the exposure area Aa, the exposure area Ab, and an exposure area Ac; the exposure head 32c is capable of exposing the exposure area Ab, the exposure area Ac, and an exposure area Ad; the exposure head 32d is capable of exposing the exposure area Ac, the exposure area Ad, and an exposure area Ae; and the exposure head 32e is capable of exposing the exposure area Ad and the exposure area Ae. Exposure areas that can be exposed are not limited to the case of exposure areas at a position corresponding to each exposure head and their adjacent exposure areas, as described above.

FIG. 4 illustrates an example of a relationship between an exposure area on a substrate and multiple exposure heads. In the example shown in FIG. 4, in the above, exposure is performed on the exposure areas (that is, the exposure area Aa for the exposure head 32a, the exposure area Ab for the exposure head 32b, the exposure area Ac for the exposure head 32c, the exposure area Ad for the exposure head 32d, and the exposure area Ae for the exposure head 32e) at a position corresponding to each exposure head.

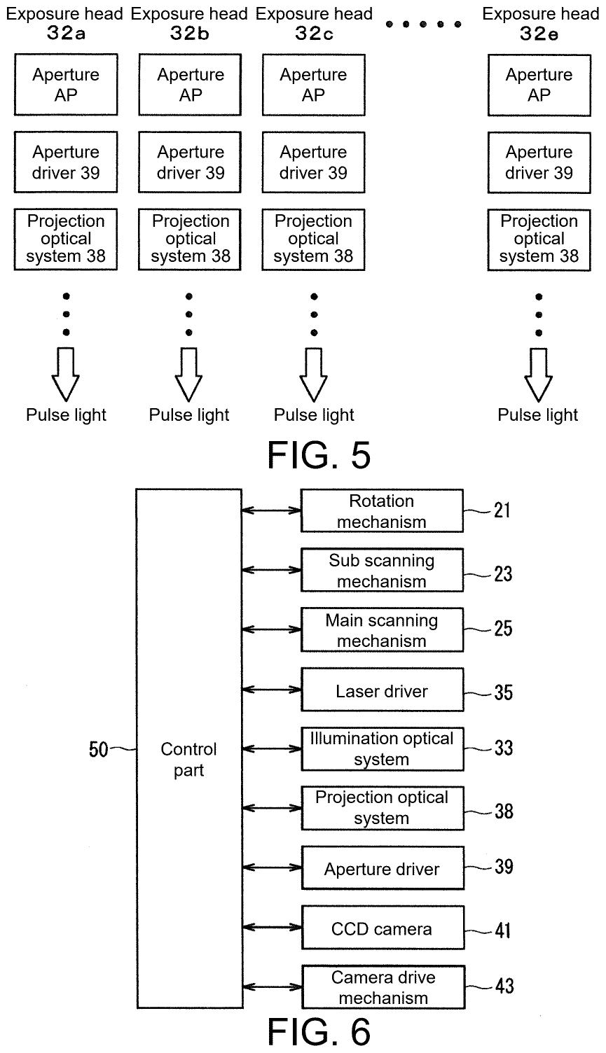

FIG. 5 conceptually illustrates a configuration of multiple exposure heads. As shown in the example in FIG. 5, the exposure head 32a, the exposure head 32b, the exposure head 32c, the exposure head 32d, and the exposure head 32e each include numerous components such as the aperture AP, the aperture driver 39, and the projection optical system 38. By normal operation of all of these components, normal pulse light is irradiated onto the substrate 9.

Returning to FIG. 1 and FIG. 2, the irradiation light capturing part 40 is a mechanism for capturing pulse light irradiated from each exposure head. The irradiation light capturing part 40 includes a CCD camera 41, a guide rail 42, and a camera drive mechanism 43 composed of a linear motor or the like. The CCD camera 41 is arranged with its capturing direction facing upward. When the camera drive mechanism 43 is operated, the CCD camera 41 moves in the sub scanning direction along the guide rail 42 attached to a side edge on the positive Y-axis direction side of the base plate 24.

When the CCD camera 41 is used, first, the main scanning mechanism 25 is operated to position the base plate 24 so that the CCD camera 41 is located below the head part 30 (state shown in FIG. 1 and FIG. 2). Then, while the camera drive mechanism 43 is operated to move the CCD camera 41 in the sub scanning direction, the pulse light irradiated from each exposure head is captured by the CCD camera 41. Image data acquired by capturing is transferred from the CCD camera 41 to the control part 50. The transferred image data is used in, for example, determining whether there is a defect in the corresponding exposure head.

The control part 50 is a processing part for controlling an operation of each driver in the exposure device 1. FIG. 6 conceptually illustrates a connection configuration between each driver of the exposure device 1 and the control part 50.

### Regarding Operation of Exposure Head

Next, an operation of one exposure head 32a among multiple exposure heads will be described. Similar operations are possible for the other exposure heads 32b, 32c, 32d, and 32e.

The pulse light emitted from the laser oscillator 34 enters the exposure head 32a via the illumination optical system 33. If there is a defect in any of the ribbons 14B of the optical modulator 33A in the illumination optical system 33 (for example, if the ribbon 14B does not move normally, or if a movable range of the ribbon 14B is narrow), light of a pixel corresponding to this ribbon 14B is not correctly modulated, and an exposure area corresponding to this light is not correctly exposed.

In FIG. 4, an area (stripe-shaped area having a width W in the X-axis direction) exposed by the exposure head 32a moving in the main scanning direction (Y-axis direction) is defined as a full exposure area, and each area exposed with light modulated by each ribbon 14B of the optical modulator 33A is defined as a sub exposure area. In the case where a defective ribbon 14B is included as described above, the sub exposure area in the full exposure area that corresponds to the defective ribbon 14B is not correctly exposed.

Thus, in the present embodiment, with a ribbon 14B among the multiple ribbons 14B in the optical modulator 33A that is determined to have no defects as a selection ribbon, the exposure head 32a is operated to expose the full exposure area by performing multiple exposures using the selection ribbon. The full exposure area also includes an area (area assigned with an exposure pattern without light irradiation) where light is not actually irradiated.

At least one of the multiple ribbons 14B in the optical modulator 33A corresponds to the above selection ribbon. It is desirable that as many normal ribbons 14B having no defects as possible are selected, and multiple ribbons 14B may be selected as selection ribbons. From the perspective of facilitating selection and operation control, multiple ribbons 14B arranged adjacent to each other may be grouped together as a selection target (selection target as area), and it may be determined whether there is a defect in the selection target including multiple ribbons 14B, and the selection target may be taken as a selection ribbon. In this case, the number of ribbons 14B grouped together may differ for each selection target. In other words, the number of ribbons 14B constituting each selection ribbon set in the optical modulator 33A may differ.

For example, the first exposure is performed using the selection ribbon with respect to a sub exposure area in the full exposure area; next, the second exposure is performed using the selection ribbon with respect to a remaining exposure area (remaining area) in the full exposure area. In this case, a movement amount of the exposure head 32a in the sub scanning direction (X-axis direction) is set to a width of the sub exposure area in the sub scanning direction (X-axis direction). If exposure is performed using a selection ribbon obtained by grouping multiple ribbons 14B together, the movement amount is set to a total width in the sub scanning direction (X-axis direction) of the multiple ribbons 14B. If multiple patterns can be set for the width of the sub exposure area due to the difference in the number of ribbons 14B included in the selection ribbon, any of the width of the sub exposure area of multiple patterns can be adopted.

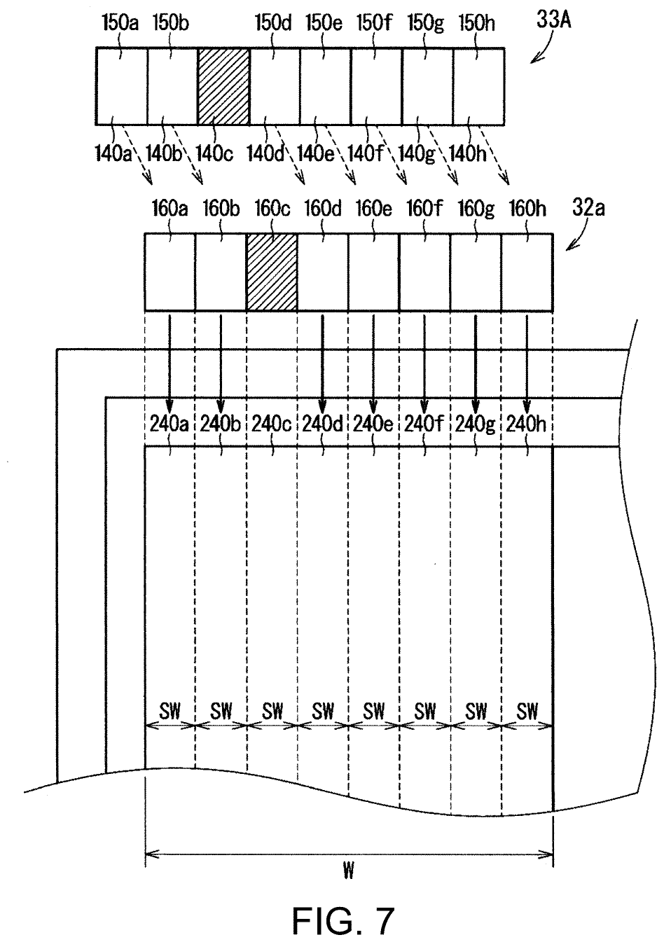

FIG. 7 illustrates an example of a relationship between the exposure area on the substrate, a head corresponding area of the exposure head 32a, and the selection ribbon of the optical modulator 33A. The size of the exposure area, the size of the head corresponding area, and the size of the selection ribbon in FIG. 7 do not reflect an actual size ratio, but conceptually show their relationship. In FIG. 7, multiple ribbons 14B are grouped together as a selection target 140a, a selection target 140b, a selection target 140c, a selection target 140d, a selection target 140e, a selection target 140f, a selection target 140g, and a selection target 140h, and a case is shown where each selection target includes the same number of ribbons 14B. In FIG. 7, the selection target 140c is taken as a selection target determined to have a defect, and the selection target 140a is selected as a selection ribbon 150a, the election target 140b as a selection ribbon 150b, the selection target 140d as a selection ribbon 150d, the selection target 140e as a selection ribbon 150e, the selection target 140f as a selection ribbon 150f, the selection target 140g as a selection ribbon 150g, and the selection target 140h as a selection ribbon 150h. On the other hand, the selection target 140c is not selected as a selection ribbon due to a failure in the ribbon 14B or the like.

In the exposure head 32a, a corresponding area is set that irradiates light modulated by each selection ribbon. Specifically, the light modulated by the selection ribbon 150a is irradiated from a head corresponding area 160a, the light modulated by the selection ribbon 150b is irradiated from a head corresponding area 160b, the light modulated by the selection ribbon 150d is irradiated from a head corresponding area 160d, the light modulated by the selection ribbon 150e is irradiated from a head corresponding area 160e, the light modulated by the selection ribbon 150f is irradiated from a head corresponding area 160f, the light modulated by the selection ribbon 150g is irradiated from a head corresponding area 160g, and the light modulated by the selection ribbon 150h is irradiated from a head corresponding area 160h.

First, in the first exposure, under the control of the control part 50, the exposure head 32a arranged at a predetermined exposure position is moved in the main scanning direction to expose the corresponding sub exposure areas using the selection ribbons 150a, 150b, 150d, 150e, 150f, 150g, and 150h. In detail, the light modulated by the selection ribbon 150a is irradiated from the head corresponding area 160a to a sub exposure area 240a, the light modulated by the selection ribbon 150b is irradiated from the head corresponding area 160b to a sub exposure area 240b, the light modulated by the selection ribbon 150d is irradiated from the head corresponding area 160d to a sub exposure area 240d, the light modulated by the selection ribbon 150e is irradiated from the head corresponding area 160e to a sub exposure area 240e, the light modulated by the selection ribbon 150f is irradiated from the head corresponding area 160f to a sub exposure area 240f, the light modulated by the selection ribbon 150g is irradiated from the head corresponding area 160g to a sub exposure area 240g, and the light modulated by the selection ribbon 150h is irradiated from the head corresponding area 160h to a sub exposure area 240h.

Under the control of the control part 50, the selection ribbon 150a is movable based on exposure data indicating modulation of light irradiated to the sub exposure area 240a, the selection ribbon 150b is movable based on exposure data indicating modulation of light irradiated to the sub exposure area 240b, the selection ribbon 150d is movable based on exposure data indicating modulation of light irradiated to the sub exposure area 240d, the selection ribbon 150e is movable based on exposure data indicating modulation of light irradiated to the sub exposure area 240e, the selection ribbon 150f is movable based on exposure data indicating modulation of light irradiated to the sub exposure area 240f, the selection ribbon 150g is movable based on exposure data indicating modulation of light irradiated to the sub exposure area 240g, and the selection ribbon 150h is movable based on exposure data indicating modulation of light irradiated to the sub exposure area 240h. In other words, instead of exposure data corresponding to the full exposure area of the exposure head 32a, exposure data indicating modulation of light irradiated to a sub exposure area corresponding to each selection ribbon is provided to each selection ribbon, and each selection ribbon is controlled based on the provided exposure data.

On the other hand, since the selection target 140c is not selected as a selection ribbon, a sub exposure area 240c corresponding to a head corresponding area 160c is not exposed.

Next, after the exposure head 32a is moved to an endpoint in the main scanning direction, the exposure head 32a is moved an amount corresponding to a sub exposure width SW in the sub scanning direction under the control of the control part 50. The sub exposure width SW corresponds to a width of a sub exposure area and is smaller than the width W of the full exposure area. In the example of FIG. 7, the sub exposure width SW is ⅛ of the width W of the full exposure area.

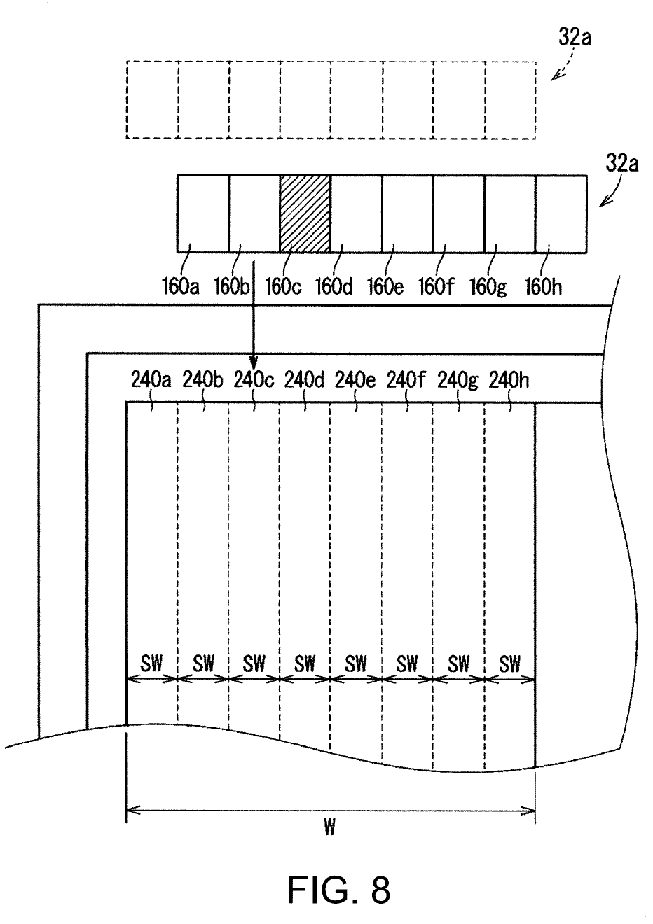

FIG. 8 illustrates an example of a relationship between the exposure area on the substrate and the head corresponding area of the exposure head 32a. FIG. 8 shows a state after the exposure head 32a has been moved the amount corresponding to the sub exposure width SW from the state in FIG. 7. The exposure head 32a shown in dotted lines in FIG. 8 is the exposure head 32a in FIG. 7 (in other words, the exposure head 32a before movement). The size of the exposure area and the size of the head corresponding area in FIG. 8 do not reflect an actual size ratio, but conceptually show their relationship.

In FIG. 8, due to the aforementioned movement, the head corresponding area 160a is arranged at a position for exposing the sub exposure area 240b, the head corresponding area 160b is arranged at a position for exposing the sub exposure area 240c, the head corresponding area 160d is arranged at a position for exposing the sub exposure area 240e, the head corresponding area 160e is arranged at a position for exposing the sub exposure area 240f, the head corresponding area 160f is arranged at a position for exposing the sub exposure area 240g, the head corresponding area 160g is arranged at a position for exposing the sub exposure area 240h, and the head corresponding area 160h is arranged at a position for exposing an area (area outside the full exposure area) further outside the sub exposure area 240h.

In the second exposure, under the control of the control part 50, the exposure head 32a is moved in the main scanning direction to irradiate the light modulated by the selection ribbon 150b from the head corresponding area 160b to the sub exposure area 240c.

The selection ribbon 150b is movable under the control of the control part 50 based on exposure data indicating modulation of light irradiated to the sub exposure area 240c. In other words, in the selection ribbon 150b, the exposure data (exposure data indicating modulation of light irradiated to the sub exposure area 240b) used for control in the first exposure is different from the exposure data (exposure data indicating modulation of light irradiated to the sub exposure area 240c) used for control in the second exposure.

On the other hand, in the second exposure, the other selection ribbons and the sub exposure area corresponding to the selection target 140c are not exposed.

By the above operations, the full exposure area can be exposed by performing multiple exposures with light modulated using the selection ribbon. Specifically, by moving the exposure head 32a to perform the second exposure so that the sub exposure area 240c that was not exposed in the first exposure is exposed by light modulated by the selection ribbon 150b, it is possible to expose the full exposure area as a total of sub exposure areas including the sub exposure area 240c using only light modulated by the selection ribbon.

Thus, even if some ribbons 14B of the optical modulator 33A have defects, by selecting a ribbon 14B other than the defective ribbons 14B as the selection ribbon and performing multiple exposures, the full exposure area can be appropriately exposed. That is, even if some ribbons 14B of the optical modulator 33A have defects, it is possible to continue appropriate exposure of the full exposure area without requiring replacement or repair of the optical modulator 33A.

In the examples of FIG. 7 and FIG. 8, the selection ribbon 150b adjacent to the selection target 140c is controlled in the second exposure, and exposure is performed on the sub exposure area 240c. However, the selection ribbon that is controlled in the second exposure to perform exposure on the sub exposure area 240c is not limited to a selection ribbon adjacent to the selection target 140c.

In FIG. 7 and FIG. 8, for convenience, the exposure head 32a is illustrated as moving in the same direction (for example, positive direction) in the main scanning direction. However, in the first exposure and the second exposure, the exposure head 32a may move in opposite directions (for example, positive direction and negative direction) in the main scanning direction.

Here, a determination method for defects for selecting a selection ribbon from multiple ribbons 14B in the optical modulator 33A will be described.

As the above determination method, for example, it is conceivable to control multiple ribbons 14B so that a maximum light amount is irradiated from the exposure head 32a, and to compare the light amount at that time and make a selection. Specifically, pulse light of the maximum light amount is irradiated from the exposure head 32a and captured by the irradiation light capturing part 40. Then, the image data acquired by capturing is analyzed by the control part 50, and for each sub exposure area, a light amount calculated from the image data is compared with a reference light amount (threshold light amount). As a result, a ribbon 14B corresponding to a sub exposure area with a small difference from the threshold light amount is determined to be a ribbon (ribbon that can be a selection ribbon) having no defects, and a ribbon 14B corresponding to a sub exposure area with a large difference from the threshold light amount is determined to be a ribbon (ribbon that cannot be a selection ribbon) having defects. The light amount used in the above comparison does not have to be the maximum light amount. The comparison may be made with the corresponding threshold light amount in multiple light amount patterns and determination accuracy may be improved.

In the above example, the analysis of image data and the determination of the modulation state of the ribbon 14B are performed by the control part 50. However, a functional part for performing the determination may be provided in the exposure device 1 separately from the control part 50.

### Regarding Other Operations of Exposure Head

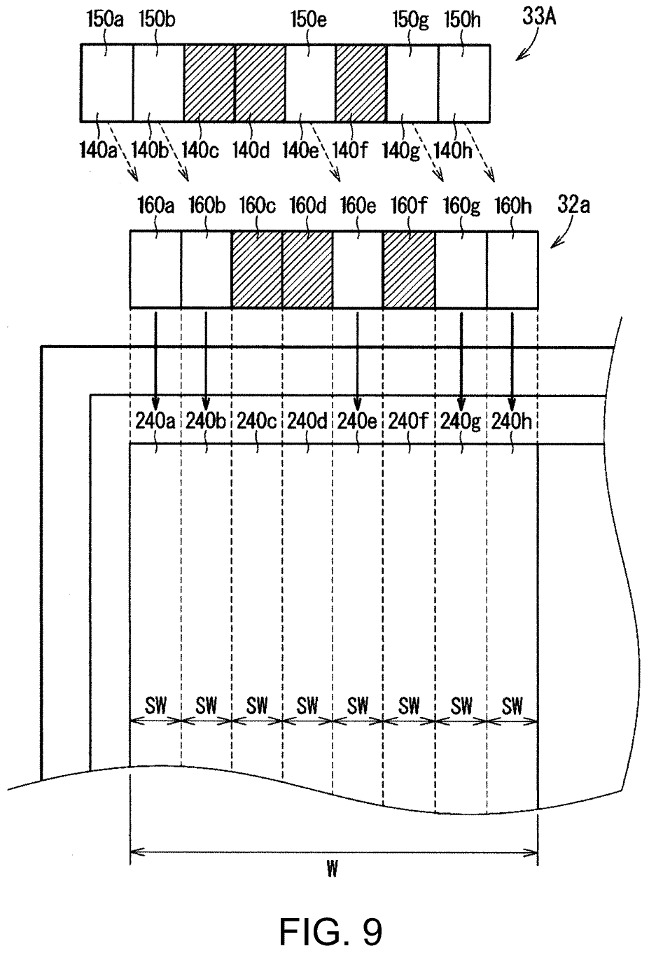

Next, another operation (three exposures) of the exposure head 32a will be described. FIG. 9 illustrates another example of the relationship between the exposure area on the substrate, the head corresponding area of the exposure head 32a, and the selection ribbon of the optical modulator 33A. The size of the exposure area, the size of the head corresponding area, and the size of the selection ribbon in FIG. 9 do not reflect an actual size ratio, but conceptually show their relationship.

In the example of FIG. 7, only the selection target 140c is not selected as a selection ribbon. In the example of FIG. 9, the selection target 140c, the selection target 140d, and the selection target 140f are determined to have defects due to a failure in the ribbon 14B or a low light amount or the like, and are not selected as selection ribbons.

First, in the first exposure, under the control of the control part 50, the exposure head 32a arranged at a predetermined exposure position is moved in the main scanning direction to expose the corresponding sub exposure areas using the selection ribbons 150a, 150b, 150e, 150g, and 150h. In detail, the light modulated by the selection ribbon 150a is irradiated from the head corresponding area 160a to the sub exposure area 240a, the light modulated by the selection ribbon 150b is irradiated from the head corresponding area 160b to the sub exposure area 240b, the light modulated by the selection ribbon 150e is irradiated from the head corresponding area 160e to the sub exposure area 240e, the light modulated by the selection ribbon 150g is irradiated from the head corresponding area 160g to the sub exposure area 240g, and the light modulated by the selection ribbon 150h is irradiated from the head corresponding area 160h to the sub exposure area 240h.

Under the control of the control part 50, the selection ribbon 150a is movable based on exposure data indicating modulation of light irradiated to the sub exposure area 240a, the selection ribbon 150b is movable based on exposure data indicating modulation of light irradiated to the sub exposure area 240b, the selection ribbon 150e is movable based on exposure data indicating modulation of light irradiated to the sub exposure area 240e, the selection ribbon 150g is movable based on exposure data indicating modulation of light irradiated to the sub exposure area 240g, and the selection ribbon 150h is movable based on exposure data indicating modulation of light irradiated to the sub exposure area 240h.

On the other hand, since the selection targets 140c, 140d, and 140f are not selected as selection ribbons, the sub exposure area 240c corresponding to the head corresponding area 160c, the sub exposure area 240d corresponding to the head corresponding area 160d, and the sub exposure area 240f corresponding to the head corresponding area 160f are not exposed.

Next, after the exposure head 32a is moved to the endpoint in the main scanning direction, the exposure head 32a is moved the amount corresponding to the sub exposure width SW in the sub scanning direction under the control of the control part 50. The sub exposure width SW corresponds to the width of the sub exposure area and is smaller than the width of the full exposure area. In the example of FIG. 9, the sub exposure width SW is ⅛ of the width W of the full exposure area.

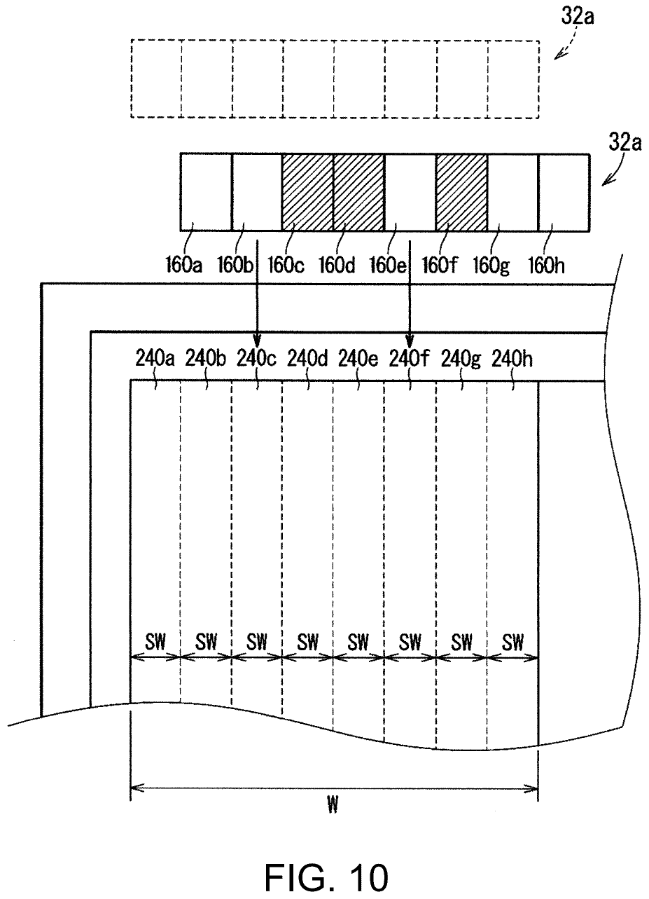

FIG. 10 illustrates an example of the relationship between the exposure area on the substrate and the head corresponding area of the exposure head 32a. FIG. 10 shows a state after the exposure head 32a has been moved the amount corresponding to the sub exposure width SW from the state in FIG. 9. The exposure head 32a shown in dotted lines in FIG. 10 is the exposure head 32a in FIG. 9 (in other words, the exposure head 32a before movement). The size of the exposure area and the size of the head corresponding area in FIG. 10 do not reflect an actual size ratio, but conceptually show their relationship.

In FIG. 10, due to the aforementioned movement, the head corresponding area 160a is arranged at a position for exposing the sub exposure area 240b, the head corresponding area 160b is arranged at a position for exposing the sub exposure area 240c, the head corresponding area 160e is arranged at a position for exposing the sub exposure area 240f, the head corresponding area 160g is arranged at a position for exposing the sub exposure area 240h, and the head corresponding area 160h is arranged at a position for exposing an area (area outside the full exposure area) further outside the sub exposure area 240h.

In the second exposure, under the control of the control part 50, the exposure head 32a is moved in the main scanning direction to irradiate the light modulated by the selection ribbon 150b from the head corresponding area 160b to the sub exposure area 240c, and to irradiate the light modulated by the selection ribbon 150e from the head corresponding area 160e to the sub exposure area 240f.

The selection ribbon 150b is movable under the control of the control part 50 based on exposure data indicating modulation of light irradiated to the sub exposure area 240c. In other words, in the selection ribbon 150b, the exposure data (exposure data indicating modulation of light irradiated to the sub exposure area 240b) used for control in the first exposure is different from the exposure data (exposure data indicating modulation of light irradiated to the sub exposure area 240c) used for control in the second exposure.

Similarly, the selection ribbon 150e is movable under the control of the control part 50 based on exposure data indicating modulation of light irradiated to the sub exposure area 240f.

On the other hand, in the second exposure, the other selection ribbons and the sub exposure areas corresponding to the selection targets 140c, 140d, and 140f are not exposed.

Furthermore, after the exposure head 32a is moved to the endpoint in the main scanning direction, the exposure head 32a is moved the amount corresponding to the sub exposure width SW in the sub scanning direction under the control of the control part 50.

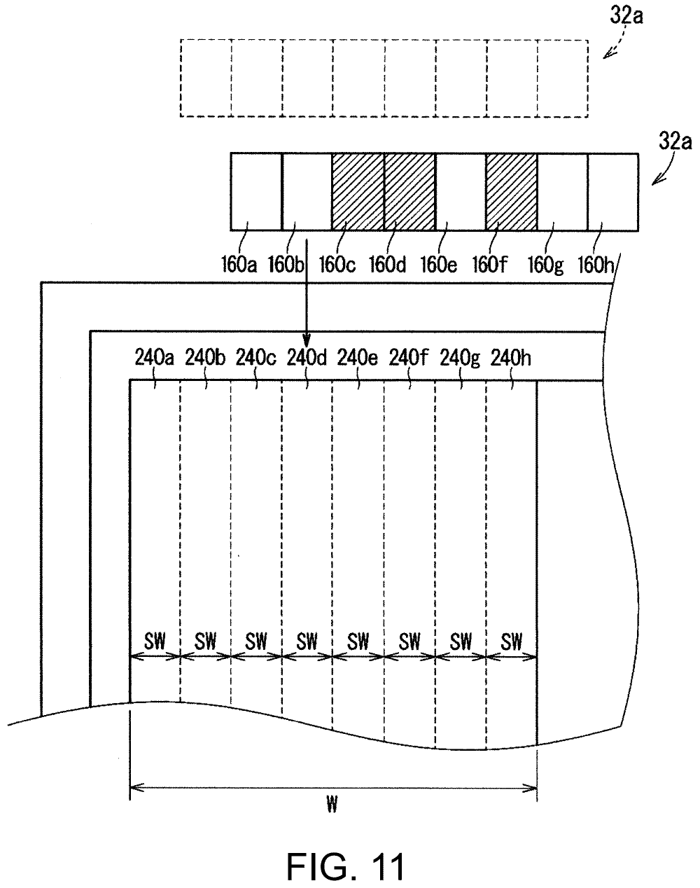

FIG. 11 illustrates an example of the relationship between the exposure area on the substrate and the head corresponding areas of the exposure head 32a. FIG. 11 shows a state after the exposure head 32a has been moved the amount corresponding to the sub exposure width SW from the state in FIG. 10. The exposure head 32a shown in dotted lines in FIG. 11 is the exposure head 32a in FIG. 10 (in other words, the exposure head 32a before movement). The size of the exposure area and the size of the head corresponding areas in FIG. 11 do not reflect an actual size ratio, but conceptually show their relationship.

In FIG. 11, due to the aforementioned movement, the head corresponding area 160a is arranged at a position for exposing the sub exposure area 240c, the head corresponding area 160b is arranged at a position for exposing the sub exposure area 240d, the head corresponding area 160e is arranged at a position for exposing the sub exposure area 240g, and the head corresponding areas 160g and 160h are arranged at a position for exposing an area (area outside the full exposure area) further outside the sub exposure area 240h.

In the third exposure, under the control of the control part 50, the exposure head 32a is moved in the main scanning direction to irradiate the light modulated by the selection ribbon 150b from the head corresponding area 160b to the sub exposure area 240d.

The selection ribbon 150b is movable under the control of the control part 50 based on exposure data indicating modulation of light irradiated to the sub exposure area 240d. In other words, in the selection ribbon 150b, the exposure data (exposure data indicating modulation of light irradiated to the sub exposure area 240b) used for control in the first exposure, the exposure data (exposure data indicating modulation of light irradiated to the sub exposure area 240c) used for control in the second exposure, and the exposure data (exposure data indicating modulation of light irradiated to the sub exposure area 240d) used for control in the third exposure are different.

On the other hand, in the third exposure, the other selection ribbons and the sub exposure areas corresponding to the selection targets 140c, 140d, and 140f are not exposed.

By the above operations, the full exposure area can be exposed by performing multiple exposures with light modulated using the selection ribbon. Specifically, by moving the exposure head 32a to perform the second and third exposures so that the sub exposure areas 240c, 240d, and 240f that were not exposed in the first exposure are exposed by light modulated by the selection ribbon 150b and the selection ribbon 150e, it is possible to expose the full exposure area as a total of sub exposure areas including the sub exposure areas 240c, 240d, and 240f using only light modulated by the selection ribbon.

Thus, even if there are defects in multiple selection targets, the full exposure area can be appropriately exposed through multiple exposures.

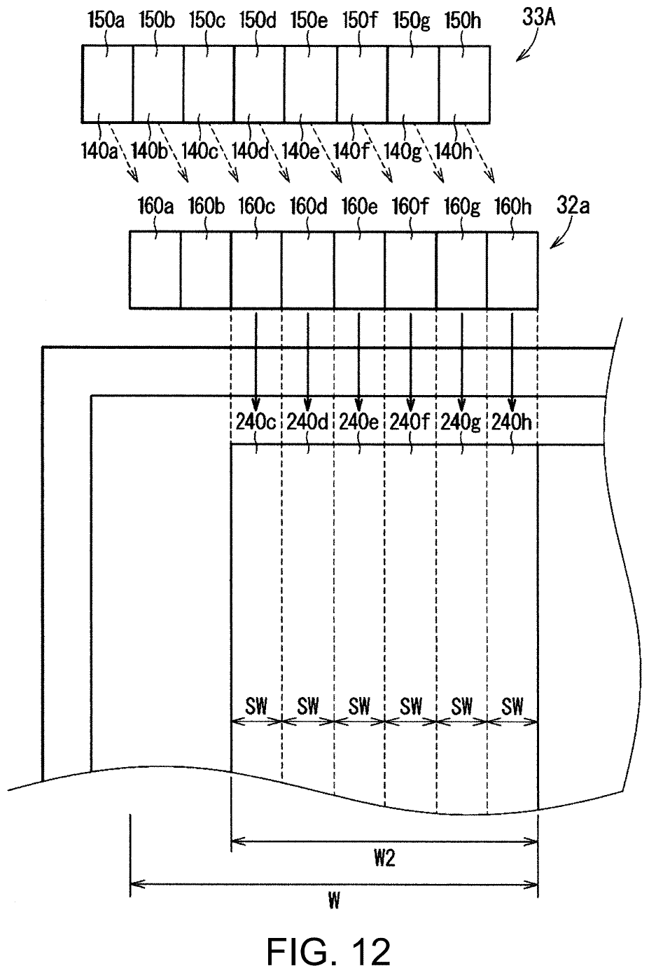

Furthermore, another operation (uniform exposure) of the exposure head 32a will be described. FIG. 12 illustrates another example of the relationship between the exposure area on the substrate, the head corresponding area of the exposure head 32a, and the selection ribbon of the optical modulator 33A. The size of the exposure area, the size of the head corresponding area, and the size of the selection ribbon in FIG. 12 do not reflect an actual size ratio, but conceptually show their relationship.

In the example of FIG. 12, the selection ribbon changes with each exposure. In the example of FIG. 12, all selection targets can be selection ribbons, but at the time of the first exposure, the selection targets 140c, 140d, 140e, 140f, 140g, and 140h are selected as selection ribbons. In other words, some of the selection targets determined to have no defects are selected as selection ribbons.

On the other hand, a width W2 of the full exposure area is smaller than the full exposure width W of the exposure head 32a. Specifically, the full exposure area is an area obtained by combining the sub exposure areas 240c, 240d, 240e, 240f, 240g, and 240h.

First, in the first exposure, under the control of the control part 50, the exposure head 32a arranged at a predetermined exposure position is moved in the main scanning direction to expose the corresponding sub exposure areas using the selection ribbons 150c, 150d, 150e, 150f, 150g, and 150h. In detail, the light modulated by the selection ribbon 150c is irradiated from the head corresponding area 160c to the sub exposure area 240c, the light modulated by the selection ribbon 150d is irradiated from the head corresponding area 160d to the sub exposure area 240d, the light modulated by the selection ribbon 150e is irradiated from the head corresponding area 160e to the sub exposure area 240e, the light modulated by the selection ribbon 150f is irradiated from the head corresponding area 160f to the sub exposure area 240f, the light modulated by the selection ribbon 150g is irradiated from the head corresponding area 160g to the sub exposure area 240g, and the light modulated by the selection ribbon 150h is irradiated from the head corresponding area 160h to the sub exposure area 240h. Each light irradiation is performed with a light amount that may achieve a desired exposure state through multiple (here, three) exposures.

Under the control of the control part 50, the selection ribbon 150c is movable based on exposure data indicating modulation of light irradiated to the sub exposure area 240c, the selection ribbon 150d is movable based on exposure data indicating modulation of light irradiated to the sub exposure area 240d, the selection ribbon 150e is movable based on exposure data indicating modulation of light irradiated to the sub exposure area 240e, the selection ribbon 150f is movable based on exposure data indicating modulation of light irradiated to the sub exposure area 240f, the selection ribbon 150g is movable based on exposure data indicating modulation of light irradiated to the sub exposure area 240g, and the selection ribbon 150h is movable based on exposure data indicating modulation of light irradiated to the sub exposure area 240h.

On the other hand, in the first exposure, since the selection targets 140a and 140b are not selected as selection ribbons, the sub exposure area 240a corresponding to the head corresponding area 160a and the sub exposure area 240b corresponding to the head corresponding area 160b are not exposed.

Next, after the exposure head 32a is moved to the endpoint in the main scanning direction, the exposure head 32a is moved the amount corresponding to the sub exposure width SW in the sub scanning direction under the control of the control part 50. The sub exposure width SW corresponds to the width of the sub exposure area and is smaller than the width W2 of the full exposure area. In the example of FIG. 12, the sub exposure width SW is ⅙ of the width W2 of the full exposure area.

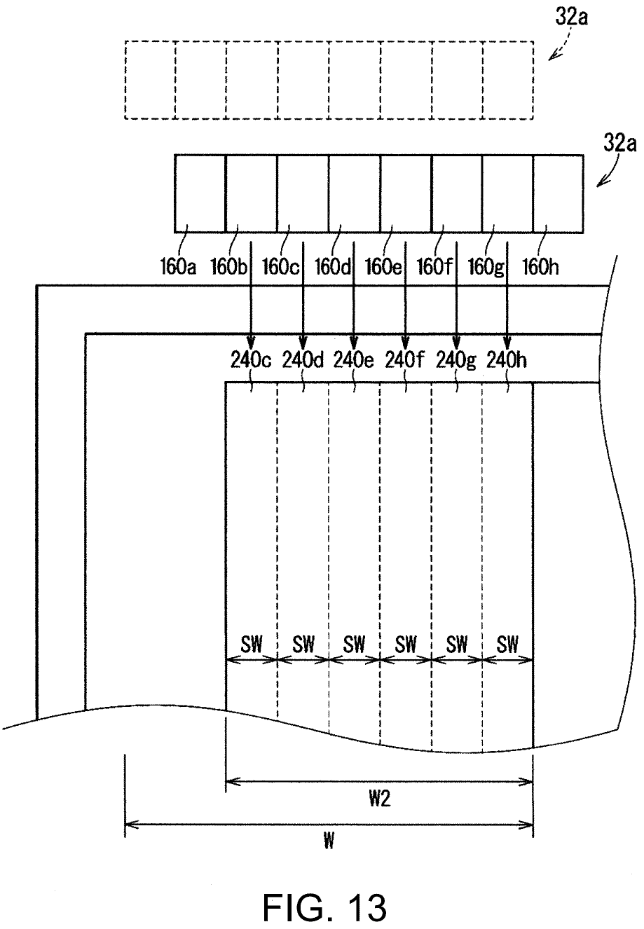

FIG. 13 illustrates an example of the relationship between the exposure area on the substrate and the head corresponding area of the exposure head 32a. FIG. 13 shows a state after the exposure head 32a has been moved the amount corresponding to the sub exposure width SW from the state in FIG. 12. The exposure head 32a shown in dotted lines in FIG. 13 is the exposure head 32a in FIG. 12 (in other words, the exposure head 32a before movement). The size of the exposure area and the size of the head corresponding area in FIG. 13 do not reflect an actual size ratio, but conceptually show their relationship.

In FIG. 13, due to the aforementioned movement, the head corresponding area 160a is arranged at a position for exposing the sub exposure area 240b, the head corresponding area 160b is arranged at a position for exposing the sub exposure area 240c, the head corresponding area 160c is arranged at a position for exposing the sub exposure area 240d, the head corresponding area 160d is arranged at a position for exposing the sub exposure area 240e, the head corresponding area 160e is arranged at a position for exposing the sub exposure area 240f, the head corresponding area 160f is arranged at a position for exposing the sub exposure area 240g, the head corresponding area 160g is arranged at a position for exposing the sub exposure area 240h, and the head corresponding area 160h is arranged at a position for exposing an area (area outside the full exposure area) further outside the sub exposure area 240h.

Here, for the second exposure, the selection targets 140b, 140c, 140d, 140e, 140f, and 140g are selected as selection ribbons.

In the second exposure, under the control of the control part 50, the exposure head 32a is moved in the main scanning direction to irradiate the light modulated by the selection ribbon 150b from the head corresponding area 160b to the sub exposure area 240c, to irradiate the light modulated by the selection ribbon 150c from the head corresponding area 160c to the sub exposure area 240d, to irradiate the light modulated by the selection ribbon 150d from the head corresponding area 160d to the sub exposure area 240e, to irradiate the light modulated by the selection ribbon 150e from the head corresponding area 160e to the sub exposure area 240f, to irradiate the light modulated by the selection ribbon 150f from the head corresponding area 160f to the sub exposure area 240g, and to irradiate the light modulated by the selection ribbon 150g from the head corresponding area 160g to the sub exposure area 240h. Each light irradiation is performed with a light amount that may achieve a desired exposure state through multiple (here, three) exposures.

Under the control of the control part 50, the selection ribbon 150b is movable based on exposure data indicating modulation of light irradiated to the sub exposure area 240c, the selection ribbon 150c is movable based on exposure data indicating modulation of light irradiated to the sub exposure area 240d, the selection ribbon 150d is movable based on exposure data indicating modulation of light irradiated to the sub exposure area 240e, the selection ribbon 150e is movable based on exposure data indicating modulation of light irradiated to the sub exposure area 240f, the selection ribbon 150f is movable based on exposure data indicating modulation of light irradiated to the sub exposure area 240g, and the selection ribbon 150g is movable based on exposure data indicating modulation of light irradiated to the sub exposure area 240h.

On the other hand, in the second exposure, since the selection targets 140a and 140h are not selected as selection ribbons, the sub exposure area 240b corresponding to the head corresponding area 160a and the area (area outside the full exposure area) corresponding to the head corresponding area 160h are not exposed.

Furthermore, after the exposure head 32a is moved to the endpoint in the main scanning direction, the exposure head 32a is moved the amount corresponding to the sub exposure width SW in the sub scanning direction under the control of the control part 50.

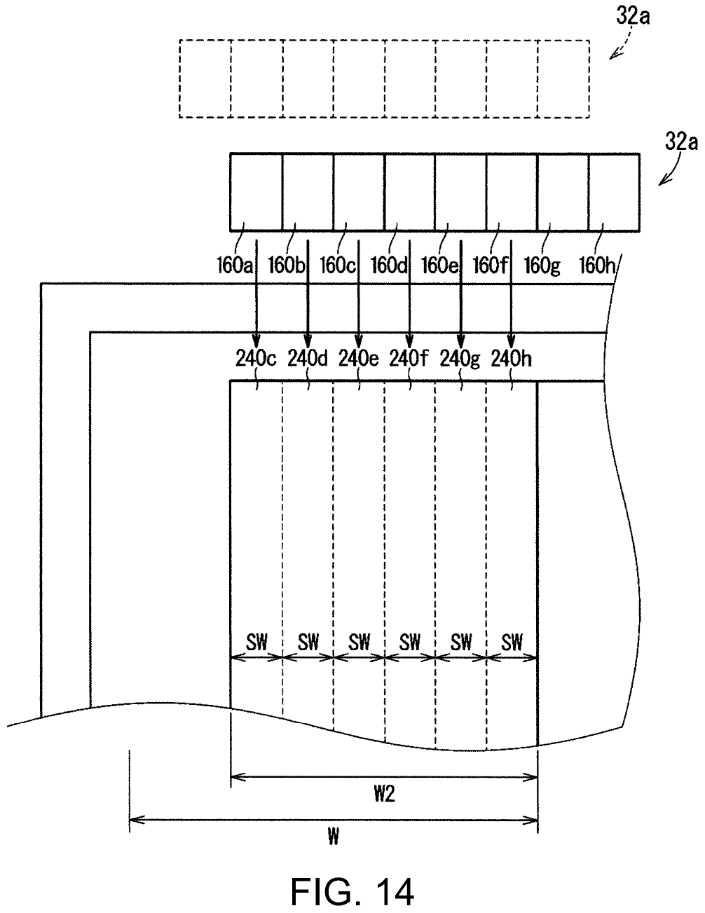

FIG. 14 illustrates an example of the relationship between the exposure area on the substrate and the head corresponding area of the exposure head 32a. FIG. 14 shows a state after the exposure head 32a has been moved the amount corresponding to the sub exposure width SW from the state in FIG. 13. The exposure head 32a shown in dotted lines in FIG. 14 is the exposure head 32a in FIG. 13 (in other words, the exposure head 32a before movement). The size of the exposure area and the size of the head corresponding area in FIG. 14 do not reflect an actual size ratio, but conceptually show their relationship.

In FIG. 14, due to the aforementioned movement, the head corresponding area 160a is arranged at a position for exposing the sub exposure area 240c, the head corresponding area 160b is arranged at a position for exposing the sub exposure area 240d, the head corresponding area 160c is arranged at a position for exposing the sub exposure area 240e, the head corresponding area 160d is arranged at a position for exposing the sub exposure area 240f, the head corresponding area 160e is arranged at a position for exposing the sub exposure area 240g, the head corresponding area 160f is arranged at a position for exposing the sub exposure area 240h, and the head corresponding areas 160g and 160h are arranged at a position for exposing an area (area outside the full exposure area) further outside the sub exposure area 240h.

Here, for the third exposure, the selection targets 140a, 140b, 140c, 140d, 140e, and 140f are selected as selection ribbons.

In the third exposure, under the control of the control part 50, the exposure head 32a is moved in the main scanning direction to irradiate the light modulated by the selection ribbon 150a from the head corresponding area 160a to the sub exposure area 240c, to irradiate the light modulated by the selection ribbon 150b from the head corresponding area 160b to the sub exposure area 240d, to irradiate the light modulated by the selection ribbon 150c from the head corresponding area 160c to the sub exposure area 240e, to irradiate the light modulated by the selection ribbon 150d from the head corresponding area 160d to the sub exposure area 240f, to irradiate the light modulated by the selection ribbon 150e from the head corresponding area 160e to the sub exposure area 240g, and to irradiate the light modulated by the selection ribbon 150f from the head corresponding area 160f to the sub exposure area 240h. Each light irradiation is performed with a light amount that may achieve a desired exposure state through multiple (here, three) exposures.

Under the control of the control part 50, the selection ribbon 150a is movable based on exposure data indicating modulation of light irradiated to the sub exposure area 240c, the selection ribbon 150b is movable based on exposure data indicating modulation of light irradiated to the sub exposure area 240d, the selection ribbon 150c is movable based on exposure data indicating modulation of light irradiated to the sub exposure area 240e, the selection ribbon 150d is movable based on exposure data indicating modulation of light irradiated to the sub exposure area 240f, the selection ribbon 150e is movable based on exposure data indicating modulation of light irradiated to the sub exposure area 240g, and the selection ribbon 150f is movable based on exposure data indicating modulation of light irradiated to the sub exposure area 240h.

On the other hand, in the third exposure, since the selection targets 140g and 140h are not selected as selection ribbons, the area (area outside the full exposure area) corresponding to the head corresponding areas 160g and 160h is not exposed.

By the above operations, the full exposure area can be exposed by performing multiple exposures with light modulated using the selection ribbon. By irradiating the same sub exposure area multiple times with light modulated by different selection ribbons, a difference in exposure amount for each sub exposure area is reduced, enabling uniform exposure across the full exposure area.

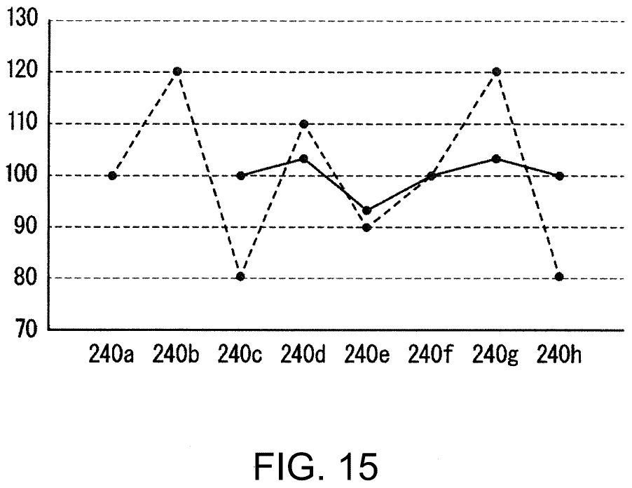

FIG. 15 illustrates an example of variations in exposure amount for each sub exposure area. In FIG. 15, the vertical axis indicates exposure amount [relative value], and the horizontal axis indicates reference numerals of the corresponding sub exposure areas.

The dotted lines in FIG. 15 indicate the exposure amount in the case where light modulated by each selection ribbon is irradiated to the corresponding sub exposure area in a single exposure. On the other hand, the solid lines in FIG. 15 indicate the exposure amount of each sub exposure area in the case of three exposures as shown in FIG. 12, FIG. 13, and FIG. 14, using the selection ribbon having the same modulation characteristics as in the case of the dotted lines.

As shown in FIG. 15, in the case of three exposures, since the same sub exposure area is irradiated multiple times with light modulated by different selection ribbons, a difference in exposure amount for each sub exposure area is offset and reduced. As a result, variations in exposure amount between sub exposure areas are reduced. In other words, uniform exposure can be performed across the full exposure area.

### Regarding Effects Produced by Embodiments Described Above

Next, examples of effects produced by the embodiments described above are shown. In the following description, the effects are described based on the specific configurations illustrated in the embodiments described above. However, these configurations may be replaced with other specific configurations illustrated in the present specification within a range in which similar effects are produced. That is, for convenience, in the following, only one of the associated specific configurations may be described as a representative. However, the specific configuration described as a representative may be replaced with other specific configurations in association therewith.

According to the embodiments described above, a direct imaging system includes a light source, the optical modulator 33A, the exposure head 32a, a first driver, a second driver, and the control part 50. Here, the light source corresponds to, for example, the laser oscillator 34. The first driver corresponds to, for example, the main scanning mechanism 25. The second driver corresponds to, for example, the sub scanning mechanism 23. The optical modulator 33A has multiple elements (ribbons 14B) arranged corresponding to the sub scanning direction. The optical modulator 33A modulates light from the laser oscillator 34. The exposure head 32a exposes the substrate 9 with light modulated by the optical modulator 33A. The main scanning mechanism 25 relatively moves the exposure head 32a in the main scanning direction intersecting the sub scanning direction with respect to the substrate 9. The sub scanning mechanism 23 relatively moves the exposure head 32a in the sub scanning direction with respect to the substrate 9. The control part 50 controls a modulation state of light in the optical modulator 33A, an operation of the main scanning mechanism 25, and an operation of the sub scanning mechanism 23. Here, at least one ribbon 14B being some of the multiple ribbons 14B of the optical modulator 33A is taken as a selection element (selection ribbon). An area exposed via the exposure head 32a with light modulated using the selection ribbon is taken as a sub exposure area. A width of the sub exposure area in the sub scanning direction is taken as the sub exposure width SW. The control part 50 relatively moves the exposure head 32a in the main scanning direction so as to expose the sub exposure area with light modulated using the selection ribbon. After the sub exposure area is exposed, the control part 50 relatively moves the exposure head 32a in the sub scanning direction an amount corresponding to the sub exposure width SW.

According to such a configuration, even if there is a defect in any of the ribbons 14B of the optical modulator 33A, light modulation and further exposure can be performed using a selection ribbon having no defects.

Here, in the related art, in an exposure device including multiple exposure heads, a technology is shown in which exposure is continued using another exposure head instead of an exposure head having defects. In such a technology, it is necessary to move the exposure head having defects from an exposure position, and it is necessary to secure a movement margin corresponding to the exposure head.

On the other hand, according to the technology of exposing using the selection ribbon shown in the present embodiment, a movement amount of the exposure head due to the occurrence of a defect in the optical modulator 33A can be reduced compared to the case of the related art. Specifically, in the related art, it is necessary to move the entire exposure head from the exposure position. However, according to the technology of exposing using the selection ribbon shown in the present embodiment, it is sufficient to shift the exposure head an amount corresponding to the sub exposure width. Accordingly, according to the present embodiment, an increase in footprint (margin for movement) can be suppressed.

Even if other configurations shown in the examples in the present specification are appropriately added to the above configuration, that is, even if other configurations in the present specification that are not mentioned as the above configuration are appropriately added, similar effects can be produced.

According to the embodiments described above, the selection ribbon includes multiple ribbons 14B arranged adjacent to each other. According to such a configuration, by arranging and grouping together multiple ribbons 14B as a selection target and taking this selection target as the selection ribbon, the selection becomes easy compared to the case of selecting each individual ribbon 14B provided in the optical modulator 33A as a selection ribbon, and the burden of light modulation control using the selection ribbon can be reduced.

According to the embodiments described above, the direct imaging system includes a selection part that selects the selection ribbon from multiple ribbons 14B. Here, the selection part corresponds to, for example, the control part 50. The control part 50 determines a light modulation state of each ribbon 14B, and selects the selection ribbon based on a result of the determination. According to such a configuration, by selecting a ribbon 14B having no defects as a selection ribbon and performing light modulation using the selection ribbon, even if there is a defect in any of the ribbons 14B of the optical modulator 33A, light modulation and further exposure can be performed.

According to the embodiments described above, an area exposed corresponding to all ribbons 14B of the optical modulator 33A is taken as a full exposure area. In the full exposure area, an area other than a sub exposure area exposed by light modulated by the selection ribbon is taken as a remaining area. After the sub exposure area is exposed, the control part 50 relatively moves the exposure head 32a the amount corresponding to the sub exposure width SW in the sub scanning direction, and relatively moves the exposure head 32a in the main scanning direction so that the remaining area is exposed with light modulated using the selection ribbon. According to such a configuration, for the remaining area other than the sub exposure area in the full exposure area, by moving the exposure head 32a the amount corresponding to the sub exposure width and then performing exposure with light modulated using the selection ribbon, even if there is a defect in any of the ribbons 14B of the optical modulator 33A, exposure can be performed on the remaining area as well using the selection ribbon.

According to the embodiments described above, multiple selection ribbons are selected, and the selection ribbons include a first selection ribbon (for example, selection ribbon 150c) and a second selection ribbon (for example, selection ribbon 150b). The control part 50 relatively moves the exposure head 32a in the main scanning direction so that the sub exposure area is exposed with light modulated using the selection ribbon 150c. After the sub exposure area is exposed, the control part 50 relatively moves the exposure head 32a the amount corresponding to the sub exposure width SW in the sub scanning direction, and relatively moves the exposure head 32a in the main scanning direction so that the same sub exposure area is exposed with light modulated using the selection ribbon 150b. According to such a configuration, by irradiating the same sub exposure area multiple times with light modulated by different selection ribbons, a difference in exposure amount for each sub exposure area is reduced, enabling uniform exposure across the full exposure area.

Since the optical performance at a minimum point is determined by various factors such as light amount distribution, lens performance, and focus performance, to uniformize the optical performance across the full exposure area, it is necessary to consider technical difficulties in optical lens adjustment or the like and high costs. On the other hand, according to the present embodiment, uniform exposure can be easily performed across the full exposure area.

According to the embodiments described above, the selection ribbon differs before and after the exposure head 32a is relatively moved the amount corresponding to the sub exposure width SW in the sub scanning direction. According to such a configuration, by having different selection ribbons before and after the relative movement of the exposure head 32a, variations of exposure with respect to the sub exposure area and the remaining area can be increased.

According to the embodiments described above, in a direct imaging method, the exposure head 32a is relatively moved in the main scanning direction to expose the sub exposure area with light modulated using the selection ribbon. After the sub exposure area is exposed, the exposure head 32a is relatively moved the amount corresponding to the sub exposure width SW in the sub scanning direction.

According to such a configuration, even if there is a defect in any of the ribbons 14B of the optical modulator 33A, light modulation and further exposure can be performed using a selection ribbon having no defects.

Unless there is a specific restriction, the order in which each processing is performed can be changed.

Even if other configurations shown in the examples in the present specification are appropriately added to the above configuration, that is, even if other configurations in the present specification that are not mentioned as the above configuration are appropriately added, similar effects can be produced.

### Regarding Modifications of Embodiment Described Above

In the embodiments described above, the material, dimensions, shape, relative arrangement relationships or implementation conditions of each component may be described. However, these are only examples in all aspects and are not limiting.

Accordingly, countless modifications and equivalents that are not shown in the examples are envisioned within the scope of the technology disclosed in the present specification. For example, cases where at least one component is modified, added, or omitted are included.

In at least one embodiment described above, when material names and the like are described without specific designation, as long as no contradiction arises, it is assumed that other additives are included in the material. For example, alloys and the like are included.

What is claimed is:

1. A direct imaging system for a substrate, comprising:
a light source;
an optical modulator, comprising a plurality of elements arranged corresponding to a sub scanning direction, the optical modulator being for modulating light from the light source;
an exposure head, for exposing the substrate with the light modulated by the optical modulator;
a first driver, for relatively moving the exposure head with respect to the substrate in a main scanning direction intersecting the sub scanning direction;
a second driver, for relatively moving the exposure head with respect to the substrate in the sub scanning direction; and
a control part, for controlling a modulation state of the light in the optical modulator, an operation of the first driver, and an operation of the second driver, wherein
at least one of the elements being some of a plurality of the elements of the optical modulator is a selection element;
an area exposed via the exposure head with the light modulated using the selection element is a sub exposure area;
a width of the sub exposure area in the sub scanning direction is a sub exposure width; and
the control part
relatively moves the exposure head in the main scanning direction to expose the sub exposure area with the light modulated using the selection element, and,
after the sub exposure area is exposed, relatively moves the exposure head an amount corresponding to the sub exposure width in the sub scanning direction.

2. The direct imaging system according to claim 1, wherein
the selection element comprises a plurality of the elements that are arranged adjacent to each other.

3. The direct imaging system according to claim 1, further comprising:
a selection part, selecting the selection element from a plurality of the elements, wherein
the selection part determines the modulation state of the light for each of the elements, and selects the selection element based on a result of the determination.

4. The direct imaging system according to claim 1, wherein
an area exposed corresponding to all the elements of the optical modulator is a full exposure area;
an area in the full exposure area other than the sub exposure area is a remaining area; and
after the sub exposure area is exposed, the control part relatively moves the exposure head the amount corresponding to the sub exposure width in the sub scanning direction, and relatively moves the exposure head in the main scanning direction so that the remaining area is exposed with the light modulated using the selection element.

5. The direct imaging system according to claim 1, wherein
a plurality of the selection elements are selected;
the selection elements comprise a first selection element and a second selection element; and
the control part
relatively moves the exposure head in the main scanning direction to expose the sub exposure area with the light modulated using the first selection element, and,
after the sub exposure area is exposed, relatively moves the exposure head the amount corresponding to the sub exposure width in the sub scanning direction, and relatively moves the exposure head in the main scanning direction so that the same sub exposure area is exposed with the light modulated using the second selection element.

6. The direct imaging system according to claim 1, wherein
the selection element differs before and after the exposure head is relatively moved the amount corresponding to the sub exposure width in the sub scanning direction.

7. A direct imaging method for a substrate using a direct imaging system that comprises an optical modulator comprising a plurality of elements arranged corresponding to a sub scanning direction and for modulating light from a light source, and an exposure head for exposing the substrate with the light modulated by the optical modulator, wherein the direct imaging method comprises:
selecting at least one of the elements being some of a plurality of the elements of the optical modulator as a selection element;
defining an area exposed via the exposure head with the light modulated using the selection element as a sub exposure area;
defining a width of the sub exposure area in the sub scanning direction as a sub exposure width;
relatively moving the exposure head in a main scanning direction intersecting the sub scanning direction to expose the sub exposure area with the light modulated using the selection element; and,
after the sub exposure area is exposed, relatively moving the exposure head an amount corresponding to the sub exposure width in the sub scanning direction.
